(19) United States
(12) Patent Application Publication
(10) Pub. No.: US 2023/0174418 A1
(43) Pub. Date: Jun. 8, 2023

(54) LOW-EMISSIVITY MATERIAL COMPRISING A SILICON NITRIDE- OR OXYNITRIDE-BASED LAYER AND A ZINC TIN OXIDE-BASED LAYER

(71) Applicant: SAINT-GOBAIN GLASS FRANCE, COURBEVOIE (FR)

(72) Inventors: Yann COHIN, PARIS (FR); Maëlis BANCI, BOURG-LA-REINE (FR); Corinne VICTOR, SAINT-LEU-LA-FORET (FR)

(21) Appl. No.: 17/924,089

(22) PCT Filed: May 7, 2021
(86) PCT No.: PCT/FR2021/050787

§ 371 Date: Nov. 8, 2022

(30) Foreign Application Priority Data
May 12, 2020 (FR) FR2004682

(51) Int. Cl. C03C 17/34; C03C 17/36

(52) U.S. Cl. CPC C03C 17/3482; C03C 17/3435; C03C 17/3607; C03C 17/3681; C03C 2217/216; C03C 2217/25

(57) ABSTRACT

A material includes a substrate coated with a stack including at least one silver-based functional metal layer and at least two dielectric coatings, each dielectric coating including at least one dielectric layer, so that each functional metal layer is between two dielectric coatings, wherein the dielectric coating located in contact with the substrate includes a layer including silicon selected from silicon oxynitride or nitride-based layers located in contact with the substrate; a layer based on zinc oxide and tin including at least 20% by mass of tin relative to the total mass of zinc and tin located in contact with the layer including silicon, the sum of thicknesses of all oxide-based layers present in the dielectric coating located between the substrate and the first functional metal layer and/or in each dielectric coating located above the first functional layer is greater than 50% of the total thickness of the dielectric coating.

The invention relates to a material comprising a transparent substrate coated with a stack comprising a silver-based functional metal layer. The invention also relates to the glazings comprising these materials and also to the use of such materials for manufacturing glazings.

Silver-based functional metal layers (or silver layers) have advantageous properties of electrical conduction and of reflection of infrared radiation (IR), hence their use in “solar control” glazings targeted at reducing the amount of solar energy entering and/or in “low-e” glazings targeted at reducing the amount of energy dissipated towards the outside of a building, vehicle, or device.

These silver layers are deposited between coatings based on dielectric materials, which generally comprise several dielectric layers (hereafter “dielectric coatings”), making it possible to adjust the optical properties of the stack. Furthermore, these dielectric layers make it possible to protect the silver layer from chemical or mechanical attacks.

The invention relates in particular to a material used to manufacture a glazing used as a constituent element of a heating or cooling device.

A heating device comprises an enclosure delimited by one or more walls and heating means so as to enable the enclosure to be heated to an elevated temperature. The heating devices can be chosen among ovens, fireplaces, furnaces, etc. According to the invention, the heating means are separate from the stack of thin layers. Heated automotive windows whose stack serves as a heating element do not correspond to a heating device according to the invention.

A cooling device comprises an enclosure delimited by one or more walls and means for cooling the enclosure to a temperature below the normal temperature (20° C.). The cooling devices can be selected from among others:
refrigerators for which the required temperatures vary between 0 and 20° C. (positive cold),
freezers for which the required temperatures are lower than 0° C. (negative cold).

The glazing used as part of a freezer-type cooling device (negative cold) is generally monolithic glass.

The glazing used as part of a heating or refrigerator-type cooling device (positive cold) is generally multiple glazing.

According to the invention, a multiple glazing comprises at least two substrates held at a distance so as to delimit a space. The faces of the glazing are designated from the inside of the heating or cooling device and by numbering the substrate faces from the inside (internal face) to the outside (external face) of the heating or cooling device.

In the case of a multiple glazing for heating devices, the different substrates are usually arranged side by side in an open space.

In the case of a multiple glazing for a refrigerator-type cooling device, the different substrates are generally connected to each other so as to form a hermetic cavity between two substrates.

These glazings help to maintain the temperature inside the device at a set temperature while keeping the outer surface of the glazing normally cool to the touch for the protection and comfort of users.

The use of substrates coated with infrared (IR) radiation reflecting functional coatings in glazings used as part of a heating or cooling device makes it possible:
to decrease the amount of energy dissipated to the outside in the case of a heating device, by reflecting the heat into the enclosure,
to decrease the amount of energy entering the enclosure in the case of a cooling device, by reflecting the heat to the outside.

The use of these coatings helps to reduce the consumption of the heating or cooling device and the heating or cooling of the glass.

Coatings comprising functional silver-based metallic layers (or silver coatings) are the most effective in reducing the emissivity of glazing while preserving their optical and aesthetic qualities. These coatings ensure better user protection, lower energy consumption, and greater comfort of use.

However, the chemical and thermal resistance and mechanical strength of the coatings comprising these silver-based functional metal layers are often insufficient. This low resistance/strength results in the short-term appearance of defects such as corrosion spots, scratches, or even total or partial tearing of the stack under normal conditions, and even more so under more extreme conditions.

This phenomenon is accentuated when these glazings are used in heating devices, especially when they are subjected to long and repeated heat treatment cycles at high temperatures in a humid environment.

This phenomenon is also accentuated when these glasses are used in cooling devices, especially when they are permanently subjected to a humid environment.

These extreme conditions further accelerate the degradation of the silver layers, particularly through dewetting or corrosion of the silver. All defects or scratches, whether due to corrosion or mechanical stresses, are liable to affect not only the optical and energy performance but also the attractiveness of the coated substrate.

The applicant has developed a functional coating that is particularly suitable for these applications. This coating consists of a single silver-based functional layer protected by an underlayer and a blocking overlayer. The dielectric coatings surrounding the functional layer are essentially oxide-based layers.

This coating is particularly suitable for cooling and heating device applications as it has both:
a high chemical durability with a resistance longer than 56 days in the High Humidity test), and
a low emissivity (about 3%).

The excellent chemical durability can be attributed to the nature of its dielectrics which are essentially oxides.

However, in order to be used in heating or cooling devices, the materials must undergo a heat treatment at high temperature such as tempering. However, the functional coating developed by the applicant remains sensitive to overheating, both during its tempering and during its potential use in a heating device. This sensitivity to heat treatment could be due to the nature of its dielectrics, composed exclusively of oxides.

The silver-based functional layer is unstable and demoulds during heat treatment at high temperatures. This de-wetting is characterized by the appearance of holes in the silver layer. These holes are called dendritic because of their often branched shape. These holes in the silver layer have two very damaging consequences for the product.

The product becomes blurred (after tempering, since the edge of the holes in the silver layer scatters the light). Visually, this blur corresponds to the appearance of a more or less milky veil. This haze can be inhomogeneous as it can reveal defects on the surface of the glass (drying marks, glass-handling suction cup marks, etc.).

The emissivity of the product, its key performance, is greatly degraded by these holes. Indeed, it can be shown that in each hole, it is no longer the emissivity of the silver layer (3%, for example) that is to be taken into account, but that of the glass (close to 89%). Thus, if the holes represent only 1% of the surface, the emissivity is already degraded by about 1.8 points, going from 3% to almost 5%.

There are a number of patent applications disclosing silver-based functional coatings comprising a thin low index layer which may be silicon oxide-based in contact with the substrate. Among these applications is EP1480920. The objective of these low index layers is to reduce the blurring following a heat treatment of stacks comprising a silver-based functional layer. These layers would reduce the negative impact of glass substrate aging by “regenerating” the surface of a potentially degraded glass substrate following, for example, long storage.

These applications or patents do not address the issue of heating or cooling devices. The maximum thickness of these intermediate layers of silicon oxide is 10 nm. Finally, these applications do not disclose stacks consisting essentially of oxide layers with advantageous chemical durability.

The applicant has surprisingly discovered that this dual optical/emissivity degradation can be largely abolished while maintaining the very good chemical durability of the product. Indeed, some technical solutions allow a strong improvement in the haze when tempering, but without keeping the necessary chemical durability of the material, which is then largely weakened.

The solution of the invention consists in using a dielectric coating located in contact with the substrate comprising:
a layer comprising silicon selected from silicon nitride- or oxynitride-based layers located directly in contact with the substrate,
a zinc tin oxide-based layer comprising at least 20% by mass of tin with respect to the total mass of zinc and tin located directly in contact with the layer comprising silicon.

The sum of the thicknesses of all oxide-based layers present in the dielectric coating between the substrate and the first functional metal layer and/or in each dielectric coating above the first functional silver-based layer is greater than 50% of the total thickness of the dielectric coating.

The dielectric coating located in contact with the substrate may comprise:
a layer comprising silicon selected from silicon oxynitride-based layers located directly in contact with the substrate,
a zinc tin oxide-based layer comprising at least 20% by mass of tin with respect to the total mass of zinc and tin located directly in contact with the layer comprising silicon.

According to this embodiment, the sum of the thicknesses of all oxide-based layers present in the dielectric coating between the substrate and the first functional metal layer and/or in one or each dielectric coating above the first functional silver-based layer is greater than 50% of the total thickness of the dielectric coating.

The dielectric coating located in contact with the substrate may comprise:
a layer comprising silicon selected from silicon nitride-based layers located directly in contact with the substrate having a thickness greater than 5 nm,
a zinc tin oxide-based layer comprising at least 20% by mass of tin with respect to the total mass of zinc and tin located directly in contact with the layer comprising silicon.

According to this embodiment, the sum of the thicknesses of all oxide-based layers present in the dielectric coating between the substrate and the first functional metal layer and/or in one or each dielectric coating above the first functional silver-based layer is greater than 60% of the total thickness of the dielectric coating.

The superior heating resistance in the presence of such a layer sequence in contact with the substrate is not only true during tempering, but also when used in a heating device.

For example, the use of the layer sequence according to the invention has 8 times the resistance to heating at a temperature of 450° C. than the same functional coating without that layer sequence. By 8 times the resistance means that the material with a stack according to the invention can be heated at the same temperature for 8 times as long as the same stack without the layer sequence according to the invention, before showing the same degree of degradation.

The applicant has found that there is a range of thickness for the layer comprising silicon that must be met in order to have an anti-haze effect and very good chemical durability. The advantageous effects of the invention are not obtained for thicknesses below 3 nm or 5 nm.

In particular, the applicant has found that the use of the layer sequence in contact with the substrate according to the invention delays the degradation of the functional coating. However, in order for this delay in degradation to be sufficient to not lead to degradation:
in the case of heat treatment at high temperature, that is, at a temperature of more than 550° C. for several minutes, or
in the case of long and repeated heating cycles (duration of more than 15 minutes) at a temperature of between 100° and 250° C., a minimum thickness for the layer comprising silicon.

Indeed, thanks to the use of the layer sequence according to the invention, the time/temperature pairing during heating becomes compatible with a transformation of the glass, such as tempering or bending, without haze or degrading emissivity. On the tempering and bending tools used, the glazing comprising a functional coating without the particular layer sequence of the invention shows haze at time and temperature parameters very close to those needed to achieve flatness, fragmentation, and acceptable shape. The industrial tools used to bend and/or temper substrates comprising functional coatings may furthermore have variabilities. A material must therefore be robust enough to accept these process variabilities. The materials of the invention have this additional strength. The observed delay in degradation (several tens of seconds at 705° C.) is sufficient to ensure that the materials will not be degraded, regardless of the variability of the tempering process.

The invention thus relates to a material comprising a transparent substrate coated with a stack comprising at least one silver-based functional metal layer and at least two dielectric coatings, each dielectric coating comprising at least one dielectric layer, so that each functional metal layer is arranged between two dielectric coatings, characterized in that:

the dielectric coating located in contact with the substrate comprises:
a layer comprising silicon selected from silicon nitride- or oxynitride-based layers located directly in contact with the substrate,
a zinc-tin oxide-based layer comprising at least 20% by mass of tin based on the total mass of zinc and tin located directly in contact with the layer comprising silicon,
   the sum of the thicknesses of all oxide-based layers present in the dielectric coating located between the substrate and the first functional metal layer and/or in each dielectric coating located above the first functional silver-based layer is greater than 50% of the total thickness of the dielectric coating.

The invention also relates to:
a glazing comprising a material according to the invention,
a glazing comprising a material according to the invention mounted on a device, on a vehicle, in particular a motor vehicle, or on a building, and
the method of preparing a material or a glazing according to the invention,
the use of a glazing according to the invention as a solar control and/or low-emissivity glazing for the building or vehicles,
a building, vehicle, or device comprising a glazing according to the invention.

The invention also relates to a heating or cooling device comprising heating or cooling means and an enclosure delimited by one or more walls, at least one wall of which comprises at least one glazing comprising a material according to the invention.

The invention is particularly suitable as a freezer-type cooling device. In this case, the glazing can be made of the material (monolithic glazing) with preferably the stack located on the face of the substrate in contact with the enclosure.

The glazing of the invention is also suitable for all applications requiring the use of a stack comprising silver layers for which resistance to repeated heat treatments and to corrosion in hot and cold humid environments are key parameters. Mention may particularly be made of:
glazings for oven doors, pyrolytic or not,
glazings for fireplace insert doors,
glazings for fireproof doors,
glazings for heating elements such as radiators and towel dryers.

The invention also relates to the use of a glazing as a component of a cooling device, a heating device or a fireproof door, the glazing comprising a material according to the invention.

The glazing can be selected from multiple glazings comprising at least two transparent substrates.

The glazing can also be made solely of the material according to the invention. In this case, it has only one substrate. It is then a simple glazing or monolithic glazing.

Throughout the description, the substrate according to the invention is regarded as laid horizontally. The stack of thin layers is deposited above the substrate. The meaning of the expressions “above” and “below” and “lower” and “upper” is to be considered with respect to this orientation. Unless specifically stipulated, the expressions “above” and “below” do not necessarily mean that two layers and/or coatings are positioned in contact with one another. When it is specified that a layer is deposited “in contact” with another layer or with a coating, this means that there cannot be one (or more) layer(s) inserted between these two layers (or layer and coating).

All the light energy characteristics presented in the description are obtained according to the principles and methods described in the European standard EN 410 relating to the determination of the light and solar characteristics of the glazings used in glass for the construction industry. It is considered that the sunlight entering a building goes from the outside to the inside.

The preferred characteristics which appear in the remainder of the description are applicable both to the material according to the invention and, where appropriate, to the glazings, devices, or method according to the invention.

The material, that is the transparent substrate coated with the stack, is intended to be subjected to a heat treatment at high temperature. As a result, the stack and the substrate have preferably been subjected to a heat treatment at a high temperature such as tempering, annealing, or bending.

The stack is deposited by magnetic-field-assisted cathode sputtering (magnetron method). According to this advantageous embodiment, all the layers of the stack are deposited by magnetic-field-assisted cathode sputtering.

The material and glazing of the invention are transparent, that is not opaque. According to an advantageous embodiment, the material or glazing according to the invention has a light transmission greater than 35%, greater than 40%, greater than 45% or greater than 50%.

Unless otherwise mentioned, the thicknesses alluded to in the present document are physical thicknesses and the layers are thin layers. Thin layer is understood to mean a layer having a thickness of between 0.1 nm and 100 micrometers.

The layers comprising silicon can be selected from silicon nitride- or oxynitride-based layers such as silicon nitride-based layers and silicon oxynitride-based layers.

The layer comprising silicon has a thickness:
greater than or equal to 3 nm, greater than or equal to 5 nm, greater than or equal to 8 nm, greater than or equal to 10 nm, or greater than or equal to 15 nm,
less than or equal to 50 nm, less than or equal to 30 nm, less than or equal to 25 nm, less than or equal to 20 nm or less than or equal to 15 nm.

Preferably, the layer comprising silicon has a thickness of between 5 and 25 nm, between 8 and 25 nm, or 8 and 15 nm.

The layers comprising silicon may comprise or consist of elements other than silicon, oxygen and nitrogen. These elements can be selected from aluminum, boron, titanium, and zirconium. Preferably, the elements are selected from amongst aluminum, boron, and titanium.

The layers comprising silicon may comprise at least 60%, at least 65%, at least 70%, at least 75.0%, at least 80%, or at least 90% by mass of silicon compared to the mass of all elements forming the layer comprising silicon other than nitrogen and oxygen.

Preferably, the layer comprising silicon comprises not more than 35%, not more than 20%, or not more than 10% by mass of elements other than silicon compared to the mass of all elements forming the layer comprising silicon other than oxygen and nitrogen.

According to one embodiment, the layers comprising silicon comprise less than 35%, less than 30%, less than 20%, less than 10%, less than 5%, or less than 1% by mass of zirconium compared to the mass of all elements forming the layer comprising silicon other than oxygen and nitrogen.

The layer comprising silicon may comprise at least 2%, at least 5.0%, or at least 8% by mass of aluminum compared to the mass all elements forming the layer comprising silicon other than oxygen and nitrogen.

The quantities of oxygen and nitrogen in a layer are determined in atomic percentages with respect to the total quantities of oxygen and nitrogen in the layer considered.

According to the invention:
the silicon oxide-based layers essentially comprise oxygen and very little nitrogen,
the silicon nitride-based layers essentially comprise nitrogen and very little oxygen,
the silicon oxynitride-based layers comprise a mixture of oxygen and nitrogen.

The silicon oxide-based layers comprise at least 90% in atomic percent of oxygen with respect to oxygen and nitrogen in the silicon oxide-based layer.

The silicon nitride-based layers comprise at least 90% in atomic percent of nitrogen with respect to oxygen and nitrogen in the silicon oxide-based layer.

The silicon oxynitride-based layers comprise 10% to 90% (exclusive of these bounds) in atomic percent of nitrogen with respect to oxygen and nitrogen in the silicon oxide-based layer.

Preferably, the silicon oxide-based layers are characterized by a refractive index at 550 nm, less than or equal to 1.55.

Preferably, the silicon nitride-based layers are characterized by a refractive index at 550 nm, less than or equal to 1.95.

Preferably, the silicon oxynitride-based layers are characterized by a refractive index at 550 nm between that of a non-nitrided oxide layer and a non-oxidized nitride layer. The silicon oxynitride-based layers preferably have a refractive index at 550 nm greater than 1.55, 1.60 or 1.70 or between 1.55 and 1.95, 1.60 and 2.00, 1.70 and 2.00 or 1.70 and 1.90.

These refractive indices can vary to some extent (±0.1) depending on the deposition conditions. Indeed, by altering on certain parameters such as pressure or the presence of doping agents, we can obtain layers of varying density, and thus a variation in refractive index.

The layer comprising silicon may be obtained
by sputtering,
from a silicon metal target or potentially a silicon oxide-based ceramic target.

The silver-based functional metal layer, before or after thermal treatment, comprises at least 95.0%, preferably at least 96.5% and better still at least 98.0% by mass of silver with respect to the mass of the functional layer.

Preferably, the silver-based functional metal layer, before thermal treatment, comprises less than 5% or less than 1.0% by mass of metals other than silver, with respect to the mass of the silver-based functional metal layer.

The silver-based functional layers have a thickness from 5 to 30 nm, 5 to 25 nm or 7 to 16 nm.

Preferably, the stack comprises just one functional layer. The stack in this case comprises just one functional layer and two dielectric coatings with at least one dielectric layer, so that each functional layer is arranged between two dielectric coatings.

The stack may comprise at least two silver-based functional metal layer and at least three dielectric coatings each comprising at least one dielectric layer, so that each functional layer is positioned between two dielectric coatings.

The stack is located on at least one side of the transparent substrate.

The stack may comprise blocking layers located below and/or above the silver-based functional metal layer.

The stack can comprise at least one blocking layer, the function of which is to protect the silver layers by preventing possible damage related to the deposition of a dielectric coating or related to a heat treatment. These blocking layers are preferably located in contact with the silver-based functional metal layers.

According to advantageous embodiments, the stack may comprise at least one blocking layer located below and directly in contact with a silver-based functional metal layer (under a blocking layer) and/or at least one blocking layer located above and directly in contact with a silver-based functional metal layer (over a blocking layer).

A blocking layer located above a silver-based functional metal layer is referred to as blocking overlayer. A blocking layer located below a silver-based functional metal layer is referred to as blocking underlayer.

The blocking layers are selected from metal layers based on a metal or on a metal alloy, the metal nitride layers, the metal oxide layers and the metal oxynitride layers of one or more elements selected from titanium, nickel, chromium, tantalum and niobium, such as Ti, TiN, TiOx, Nb, NbN, NbOx, Ni, NiN, NiOx, Cr, CrN, CrOx, NiCr, NiCrN, or NiCrOx.

When these blocking layers are deposited in the metal, nitride or oxynitride form, these layers can undergo a partial or complete oxidation according to their thickness and the nature of the layers which surround them, for example, during the deposition of the following layer or by oxidation in contact with the underlying layer.

The blocking layers may be selected from metal layers, in particular an alloy of nickel and chromium (NiCr) or titanium.

Advantageously, the blocking layers are nickel-based metallic layers. Nickel-based metal blocking layers may comprise, (before heat treatment), at least 20%, at least 30%, at least 40%, at least 50%, at least 60%, at least 70%, at least 80%, at least 90%, at least 95%, at least 96%, at least 97%, at least 98%, at least 99%, or 100% by mass of nickel with respect to the mass of the nickel-based metal layer.

Nickel-based metal layers can be selected from:
nickel metal layers,
doped nickel metal layers,
nickel alloy-based metal layers.

Nickel alloy-based metal layers can be based on nickel-chromium alloy.

Each blocking layer has a thickness of between 0.1 and 5.0 nm. The thickness of these blocking layers can be:
at least 0.1 nm, at least 0.2 nm or at least 0.4 nm and/or
at most 5.0 nm, at most 2.0 nm, at most 1.0 nm or at most 0.5 nm.

“Dielectric coating” within the meaning of the present invention should be understood as meaning that there may be just one layer or several layers of different materials inside the coating. A “dielectric coating” according to the invention comprises mostly dielectric layers. However, according to the invention, these coatings can also comprise layers of another nature, in particular absorbent layers, for example metallic ones.

A “same” dielectric coating is considered to be:
between the substrate and the first functional layer,
between each silver-based functional metal layer,
above the last functional layer (furthest from the substrate).

“Dielectric layer” within the meaning of the present invention should be understood as meaning that, from the perspective of its nature, the material is “nonmetallic”, that is, is not a metal. In the context of the invention, this term refers to a material with an n/k ratio across the visible spectrum (from 380 nm to 780 nm) equal to or greater than 5. n denotes the real refractive index of the material at a given wavelength and k represents the imaginary part of the refractive index at a given wavelength; the ratio n/k being calculated at a given wavelength being identical for n and for k.

The thickness of a coating corresponds to the sum of the optical thicknesses of the layers which form it.

The coatings exhibit a thickness of greater than 15 nm, preferably of between 15 and 200 nm.

The dielectric layers of the coatings exhibit the following characteristics, alone or in combination:
they are deposited by sputtering assisted by a magnetic field,
they are selected from the oxides or nitrides of one or more elements chosen from titanium, silicon, aluminum, zirconium, tin and zinc,
they have a thickness greater than 2 nm, preferably between 2 and 100 nm

Preferably, the silver-based functional layer is located above a dielectric layer, the so-called stabilizing or wetting layer, made of a material capable of stabilizing the interface with the functional layer. These coatings are usually based on zinc oxide.

Preferably, the silver-based functional layer is located below a dielectric layer, the so-called stabilizing or wetting layer, made of a material capable of stabilizing the interface with the functional layer. These coatings are usually based on zinc oxide.

Zinc oxide-based coatings may comprise at least 80% or at least 90% by mass of zinc, with respect to the total mass of all the elements constituting the zinc oxide coating, excluding oxygen and nitrogen.

The zinc oxide-based layers may comprise one or more elements selected from aluminum, titanium, niobium, zirconium, magnesium, copper, silver, gold, silicon, molybdenum, nickel, chromium, platinum, indium, tin and hafnium, preferably aluminum.

The zinc oxide-based layers may optionally be doped by means of at least one other element, such as aluminum.

The zinc oxide-based coating is not nitrided, but traces of it may exist.

The layer based on zinc oxide comprises, in increasing order of preference, at least 80%, at least 90%, at least 95%, at least 98%, or at least 100% by mass of oxygen relative to the mass of oxygen and nitrogen.

The dielectric coating located between the substrate and the first functional metal layer and/or the or each dielectric coating located above the first functional silver-based layer comprises a zinc oxide-based layer comprising at least 80% by mass zinc with respect to the mass of all elements other than oxygen.

Preferably, each dielectric coating comprises a zinc oxide-based layer comprising at least 80% by mass of zinc with respect to the mass of all elements other than oxygen.

Preferably, the dielectric coating located directly below the silver-based functional metal layer comprises at least one dielectric layer based on zinc oxide, potentially doped with at least one other element, like aluminum. The metal functional layer deposited above a zinc oxide-based layer is either in direct contact or separated by a blocking layer.

In all stacks, the dielectric coating closest to the substrate is called the bottom coating and the dielectric coating farthest from the substrate is called the top coating. Stacks with more than one silver layer also comprise intermediate dielectric coatings located between the bottom and top coatings.

Preferably, the bottom or intermediate coatings comprise a dielectric layer based on zinc oxide located beneath and directly in contact with a silver-based metal layer, or separated from that layer by a blocking underlayer.

Preferably, the dielectric coating located directly above the silver-based functional metal layer comprises at least one dielectric layer based on zinc oxide, potentially doped with at least one other element, like aluminum. The metal functional layer deposited below a zinc oxide-based layer is either in direct contact or separated by a blocking layer.

Preferably, the intermediate or top coatings comprise a dielectric layer based on zinc oxide located above and directly in contact with a silver-based metal layer, or separated from that layer by a blocking overlayer.

The zinc oxide layers have a thickness of:
at least 1.0 nm, at least 2.0 nm, at least 3.0 nm, at least 4.0 nm, or at least 5.0 nm, and/or
at most 25 nm, at most 10 nm or at most 8.0 nm.

The dielectric layers may have a barrier function. Dielectric layers having a barrier function (hereinafter barrier layer) is understood to mean a layer made of a material capable of forming a barrier to the diffusion of oxygen and water at high temperatures, originating from the ambient atmosphere or from the transparent substrate, toward the functional layer. Such dielectric layers are chosen among the layers:
based on silicon and/or aluminum and/or zirconium compounds selected from oxides such as SiO2, nitrides such as silicon nitride Si3N4 and aluminum nitrides AlN, and oxynitrides SiOxNy, optionally doped with at least one other element,
based on zinc-tin oxide,
based on titanium oxide.

Preferably, the material comprises one or more layers based on zinc-tin oxide. The zinc-tin oxide-based layers comprise at least 20% by mass of tin with respect to the total mass of zinc and tin.

The zinc-tin oxide-based layer comprises at least 20%, at least 30%, at least 40%, at least 50%, at least 60% or at least 80% by mass of tin, with respect to the total mass of zinc and tin.

Preferably, the zinc-tin oxide-based layer comprises 40 to 80% by mass of tin with respect to the total mass of zinc and tin.

The zinc-tin oxide-based layer has a thickness:
greater than 5 nm, greater than 10 nm, greater than 15 nm, greater than 20 nm, greater than 25 nm
less than 50 nm, less than 40 nm, less than 35 nm.

Each dielectric coating may comprise a zinc-tin oxide-based layer comprising at least 20% by mass of tin with respect to the total mass of zinc and tin.

Preferably, the stack comprises at least one zinc oxide dielectric layer and one zinc-tin oxide layer.

Preferably, the dielectric coating located directly below the silver-based functional metal layer comprises at least one dielectric layer based on zinc oxide and a layer based on zinc-tin oxide.

Preferably, one or each dielectric coating located directly above the silver-based functional metal layer comprises at least one dielectric layer based on zinc oxide and a layer based on zinc-tin oxide.

Preferably, each dielectric coating comprises at least one zinc oxide dielectric layer and one zinc-tin oxide layer.

According to the invention, oxide-based layers are considered to be those which contain a majority of oxygen (relative to nitrogen). Nitride and oxynitride layers are not considered to be oxide layers.

The oxide-based layers according to the invention comprise, in order of increasing preference, at least 90% atomic percent oxygen relative to the total amount of oxygen and nitrogen in the layer.

Preferably, the sum of the thicknesses of all zinc-tin oxide layers in the dielectric coating between the substrate and the first silver layer is greater than 30%, greater than 40%, greater than 50% or greater than 60% of the total thickness of the dielectric coating.

Preferably, the sum of the thicknesses of all zinc-tin oxide layers in the dielectric coating above a silver functional layer is greater than 50%, greater than 60%, greater than 70% or greater than 75% of the total thickness of the dielectric coating.

Preferably, the sum of the thicknesses of all oxide-based layers present in the dielectric coating between the substrate and the first functional metal layer is greater than 50%, greater than 55% or greater than 60% of the total thickness of the dielectric coating.

Preferably, the sum of the thicknesses of all oxide-based layers present in each dielectric coating above the first functional silver-based layer is greater than 50%, greater than 60%, greater than 70%, greater than 80% or greater than 90% of the total thickness of the dielectric coating.

Each dielectric coating located above the first functional silver layer may consist solely of oxide layer.

The stack of thin layers can optionally comprise a protective layer. The protective layer is preferably the final layer of the stack, that is to say the layer the furthest away from the substrate coated with the stack (before heat treatment).

The dielectric coating furthest from the substrate may comprise a protective layer.

These layers generally have a thickness comprised between 0.5 and 10 nm, preferably 1 and 5 nm. This protective layer can be selected from a layer based on titanium, zirconium, hafnium, zinc and/or tin and a mixture thereof, this or these metals being in the metal, oxide or nitride form.

According to one embodiment, the protective layer is based on zirconium oxide and/or titanium oxide, preferably based on zirconium oxide, titanium oxide or titanium-zirconium oxide.

According to one embodiment, the stack comprises:
a dielectric coating below the silver-based functional metal layer,
optionally a blocking layer,
a silver-based functional metal layer,
optionally a blocking layer,
a dielectric coating above the silver-based functional metal layer optionally comprising a protective layer.

According to one embodiment, the stack comprises:
a dielectric coating below the silver-based functional metal layer comprising the layer comprising silicon, a zinc-tin oxide-based layer, a zinc oxide based-layer,
optionally a blocking layer,
a silver-based functional metal layer,
optionally a blocking layer,
a dielectric coating on top of the silver-based functional metal layer comprising a zinc oxide-based layer, a zinc-tin oxide-based layer and optionally a protective layer.

The coated substrate of the stack, or the stack alone, may be intended to undergo heat treatment. The substrate coated with the stack can be bent and/or tempered. However, the present invention also relates to the coated substrate that is not heat-treated.

The stack might not have been heat-treated at a temperature above 500° C., preferably 300° C.

The stack might have been heat-treated at a temperature above 300° C., preferably 500° C.

The heat treatments are chosen from an annealing, for example from a rapid thermal process such as a laser or flash annealing, a tempering and/or a bending. The rapid thermal process is for example described in application WO2008/096089.

The heat treatment temperature (on the stack) is greater than 300° C., preferably greater than 400° C. and better still greater than 500° C.

The coated substrate of the stack is preferably a tempered glass, especially when it is part of a glazing used as a component of a cooling device, a heating device or a fireproof door.

The transparent substrates according to the invention are preferably made of a rigid inorganic material, such as made of glass, or are organic, based on polymers (or made of polymer).

The organic transparent substrates according to the invention can also be made of polymer, and are rigid or flexible. Examples of polymers which are suitable according to the invention comprise, in particular:
polyethylene,
polyesters such as polyethylene terephthalate (PET), polybutylene terephthalate (PBT), polyethylene naphthalate (PEN);
polyacrylates such as polymethyl methacrylate (PMMA);
polycarbonates;
polyurethanes;
polyamides;
polyimides;
fluorinated polymers such as fluoresters like ethylene tetrafluoroethylene (ETFE), polyvinylidene fluoride (PVDF), polychlorotrifluoroethylene (PCTFE), ethylene chlorotrifluoroethylene (ECTFE), fluorinated ethylene-propylene copolymers (FEP);
photocrosslinkable and/or photopolymerizable resins, such as thiol-ene, polyurethane, urethane-acrylate, polyester-acrylate; and
polythiourethane resins.

The substrate is preferably a sheet of glass or of glass-ceramic.

The substrate is preferably transparent, colorless (it is then a clear or extra-clear glass) or colored, for example blue, gray or bronze. The glass is preferably of soda-lime-silica type but it can also be a glass of borosilicate or alum ino-borosilicate type.

According to a preferred embodiment, the substrate is made of glass, particularly soda-lime-silica glass, or of polymer organic material.

The substrate advantageously has at least one dimension greater than or equal to 1 m, indeed even 2 m and even 3 m. The thickness of the substrate generally varies between 0.5 mm and 19 mm, preferably between 0.7 and 9 mm, in particular between 2 and 8 mm, indeed even between 2.8 and 6 mm. The substrate may be flat or curved, indeed even flexible.

The invention also relates to a glazing comprising at least a material according to the invention. The invention relates to a glazing that can be in the form of a monolithic, laminated or multiple glazing, in particular double glazing or triple glazing.

The glazing may be a monolithic glazing comprising 2 faces.

The glazing can be a multiple glazing comprising two, three or four substrates. In this case, the glazing comprises a material according to the invention, particularly comprising a substrate and one, two, or three additional substrates.

A multiple glazing comprises at least one material according to the invention and at least one additional substrate. The material and the additional substrate are either side-by-side or separated by at least one interposed gas gap.

A double glazing has two substrates, an outer and an inner substrate, and 4 faces.

A triple glazing has three substrates, an outer substrate, a central substrate and an inner substrate, and six faces.

In the case of a building, the face 1 is outside the building and is therefore the outer wall of the glazing. All other sides are numbered successively. The face inside the building has the highest number.

A laminated glazing comprises at least one structure of first substrate/sheet(s)/second substrate type. The polymer sheet may especially be based on polyvinyl butyral PVB, ethylene vinyl acetate EVA, polyethylene terephthalate PET, polyvinyl chloride PVC. The stack of thin layers is positioned on one at least of the faces of one of the substrates.

These windows can be mounted on a building or a vehicle.

This glass can be mounted on heating or cooling devices such as oven or refrigerator doors.

The glazing may comprise at least one transparent substrate coated with a functional coating other than a stack comprising at least one silver-based functional metal layer such as a coating comprising a transparent conductive oxide (“TCO”). The coating comprising a transparent conductive oxide can be selected from indium tin oxide (ITO), aluminum-doped zinc oxide (ZnO:Al) or boron-doped zinc oxide (ZnO: B), or based on fluorine-doped tin oxide (SnO2: F). These materials are deposited chemically, such as by chemical vapor deposition (“CVD”), possibly plasma enhanced (“PECVD”) or physically, such as by vacuum sputtering, possibly assisted by a magnetic field (“Magnetron”). The presence of this other coating is particularly advantageous in the case of heating devices.

The functional coating other than a stack comprising at least one silver-based functional metal layer may be on the same substrate. The functional coating other than a stack comprising at least one silver-based functional metal layer may be on a different substrate than one coated with a stack comprising a silver-based functional metal layer. In this case the glazing is a multiple glazing.

The glazing may therefore comprise a functional coating other than a stack comprising a silver-based functional metal layer such as a coating comprising a transparent conductive oxide located:
on the substrate comprising a silver-based functional metal layer, on the face opposite that comprising the silver-based functional metal layer,
on one of the faces of a substrate different from that comprising a silver-based functional metal layer.

The heating device allows the heating of the enclosure to a high temperature, in particular above 50, 100, 200, 300, 400, 500 or 600° C. The heating device further comprises heating means. These heating means allow the heating of the enclosure to a high temperature, in particular above 50, 100, 200, 300, 400, 500 or 600° C.

The following examples illustrate the invention.

### EXAMPLES

Stacks of thin layers defined below are deposited on substrates made of clear soda-lime glass with a thickness of 4 mm.

For these examples, the conditions of the deposition of the layers deposited by sputtering (“magnetron cathode” sputtering) are summarized in table 1 below.

TABLE 1

| | | Pressure | | |
|---|---|---|---|---|
| Table | Targets employed | μbar | Gas | Index |
| Si3N4 | Si:Al 92/8% by wt | 2 | Ar 34%-N₂ 66% | 2.05 |
| SiON | Si:Al 92/8% by wt | 2 | Ar 15%-O₂ 9%-N₂ 76% | 1.7 |
| SnZnO | Sn:Zn 60/40% by wt | 2 | Ar 25%-O₂ 75% | 2.05 |
| ZnO | Zn:Al(92/8%)Ox | 2 | Ar at 100% | 2.0 |
| NiCr | Ni:Cr (80:20% at.) | 2 | Ar at 100% | — |
| Ag | Ag | 4 | Ar at 100% | — |
| TiOₓ | TiOx | 2 | Ar 88%-O₂ 12% | 2.35 |

at.: atomic; wt: weight; *: at 550 nm.

The materials and the physical thicknesses in nanometers (unless otherwise indicated) of each layer or coating of which the stacks are composed are listed in Table 2 below as a function of their positions with regard to the substrate carrying the stack.

TABLE 2

| | | | Inv. | Inv. | Inv. | Inv. | Inv. | Inv. |
|---|---|---|---|---|---|---|---|---|
| Glazing | | Cp-1 | 1-1 | 1-2 | 1-3 | 2-1 | 2-1 | 2-3 |
| DC | TiOx | 3 | 3 | 3 | 3 | 3 | 3 | 3 |
| | SnZnO | 41 | 41 | 41 | 41 | 41 | 41 | 41 |
| | ZnO | 7 | 7 | 7 | 7 | 7 | 7 | 7 |
| BL | NiCr | 0.4 | 0.4 | 0.4 | 0.4 | 0.4 | 0.4 | 0.4 |
| FL | Ag | 12.5 | 12.5 | 12.5 | 12.5 | 12.5 | 12.5 | 12.5 |
| BL | NiCr | 0.1 | 0.1 | 0.1 | 0.1 | 0.1 | 0.1 | 0.1 |
| DC | ZnO | 7 | 7 | 7 | 7 | 7 | 7 | 7 |
| | SnZnO | 30 | 26 | 21 | 17 | 25 | 20 | 21 |
| | SiON | 0 | 5 | 10 | 15 | — | — | |
| | SiN | 0 | — | — | — | 5 | 10 | 15 |
| Sub. | Glass | — | — | — | — | — | — | — |

DC: Dielectric coating; BL: Blocking layer; FL: Functional layer.

In order to preserve the optical properties of cp-1, the Inv-1 and Inv-2 stacks must be corrected. This involves reducing the thickness of SnZnO under the silver layer, in proportion to the thickness and optical index of the layer comprising silicon.

A heat treatment is performed on the coated substrates at 650° C. for 10 minutes.

Evaluation of Haze and Chemical Durability.

The level of haze was quantified in the following way: After thermal treatment, the tempered glass is placed on a desk tilted 20 degrees from the vertical, in a room with black walls. It is lit by a powerful lamp placed vertically on the desk. The observer stands in front of the desk, 1 m away. In this configuration, a hazy sample shows a marked milky appearance: It scatters the light from the lamp away from its specular reflection area on the glass. On the other hand, a sample without haze does not diffuse any light towards the observer, so it appears dark. The following assessment indicators were used:
“-”: The material is very hazy,
“0”: The material is hazy,
“+”: The material is not hazy.

Chemical durability is evaluated by a high humidity test before (HH) and after heat treatment (TT-HH). The humidity (HH) test consists in storing samples for 56 days at 90% relative humidity and at 60° C. and observing the possible presence of defects, such as corrosion pits. The following assessment indicators were used:
ok: no pitting, the material has no defects after 56 days of testing,
nok: much pitting, the material has defects and therefore does not pass the test.

The results are compiled in table 3 below.

TABLE 3

| Test | Cp-1 | Inv-1-1 | Inv-1-2 | Inv-1-3 | Inv-2 | Inv-2-2 | Inv-2-3 |
|---|---|---|---|---|---|---|---|
| Haze | − | + | + | + | + | + | + |
| HH | ok | ok | ok | ok | ok | ok | ok |
| TT-HH | ok | ok | ok | ok | ok | ok | ok |

Study of Emissivity Degradation Based on Heat Treatment Duration

The applicant has found that the advantageous properties of the invention in terms of resistance to heat treatment are attributable to delayed degradation. This delay is observed when the stack comprises the layer sequence according to the invention in contact with the substrate.

This delay is illustrated by comparative curves representing the emissivity degradation in percentage points based on heat treatment duration in seconds. The heat treatment is performed at a temperature of 705° C. The material Cp-1 is compared to the materials of the invention. To evaluate the degradation, the duration of the heat treatment in seconds is compared, for which 2 points of emissivity degradation are obtained between the material Cp-1 and the materials of the invention respectively. For each material according to the invention, a delay of well over 30 s is observed.

Indeed, thanks to the use of the layer sequence according to the invention, the time/temperature pairing during heating becomes compatible with a transformation of the glass, such as tempering or bending, without haze or degrading emissivity. On the tempering and bending tools used, the glazing Cp-1 showed haze at time and temperature parameters very close to those needed to achieve flatness, fragmentation, and acceptable shape. The industrial tools used to bend and/or temper a coated glass may vary. A glazing must therefore be robust enough to accept these process variabilities. The materials of the invention have this additional strength. The observed 30-second delay is sufficient to ensure that the materials will not be degraded, regardless of the variability of the tempering process.

Finally, when a 15-minute treatment is performed at 630° C., the material Cp-1 is degraded. In particular, we observe a degradation of emissivity of more than 5 percentage points. By comparison, no degradation of emissivity is observed for the materials of the invention when heat-treated at this temperature, even when the duration of the heat treatment is much longer (22 minutes).

Table 5 below shows the impact of a heat treatment at 650° C. for 15 minutes on the emissivity. The emissivity before heat treatment for each material is approximately 3.7 to 4%.

TABLE 5

| | Emissivity |
|---|---|
| Material | (%) |
| Cp. 1 | 8.9 |
| Inv. 1-1 | 2.8 |
| Inv. 1-2 | 2.8 |
| Inv. 1-3 | 2.9 |
| Inv. 2-1 | 3.1 |
| Inv. 2-2 | 3.3 |
| Inv. 2-3 | 2.9 |

Heavy degradation is observed for the material Cp-1 and a significant gain for each material of the invention.

1. A material comprising a transparent substrate coated with a stack comprising at least one functional metal layer comprising silver and at least two dielectric coatings, each dielectric coating comprising at least one dielectric layer, so that each functional metal layer is arranged between two dielectric coatings, wherein the:
dielectric coating located in contact with the transparent substrate comprises:
a layer comprising silicon selected from silicon oxynitride or nitride-based layers located directly in contact with the transparent substrate,
a layer based on zinc oxide and tin comprising at least 20% by mass of tin relative to the total mass of zinc and tin located directly in contact with the layer comprising silicon,
a sum of thicknesses of all oxide-based layers present in the dielectric coating located between the transparent substrate and a first functional metal layer of the at least one functional metal layer and/or in each dielectric coating located above the first functional metal layer is greater than 50% of a total thickness of the dielectric coating.

2. The material according to claim 1, wherein the layer comprising silicon has a thickness of greater than or equal to 5 nm.

3. The material according to claim 1, wherein the layer comprising silicon has a thickness of between 8 and 25 nm.

4. The material according to claim 1, wherein the layer comprising silicon comprises at least 60% by mass of silicon relative to the mass of all elements other than nitrogen and oxygen.

5. The material according to claim 1, wherein the layer comprising silicon comprises a silicon oxynitride layer having a refractive index at 550 nm that is between 1.60 and 2.00.

6. The material according to claim 1, wherein the dielectric coating located between the transparent substrate and the first functional metal layer and/or one or each dielectric coating located above the first functional metal layer comprises a zinc oxide-based layer comprising at least 80% by mass of zinc with respect to the mass of all elements other than oxygen.

7. The material according to claim 1, wherein each dielectric coating located above the first functional metal layer comprises a zinc-tin oxide-based layer comprising at least 20% tin by mass with respect to the total mass of zinc and tin.

8. The material according to claim 1, wherein the dielectric coating located between the transparent substrate and the first functional metal layer comprises at least one zinc-tin oxide-based layer and a zinc oxide-based dielectric layer.

9. The material according to claim 1, wherein each dielectric coating comprises at least one zinc oxide-based dielectric layer and a zinc-tin oxide-based layer.

10. The material according to claim 1, wherein the sum of the thicknesses of all oxide-based layers present in the dielectric coating located between the transparent substrate and the first functional metal layer is greater than 60% of the total thickness of the dielectric coating.

11. The material according to claim 1, wherein the sum of the thicknesses of all oxide-based layers present in the dielectric coating located between the transparent substrate and the first functional metal layer is greater than 70% of the total thickness of the dielectric coating.

12. The material according to claim 1, wherein the sum of the thicknesses of all oxide-based layers present in each dielectric coating located above the first functional metal layer is greater than 60% of the total thickness of the dielectric coating.

13. The material according to claim 1, wherein at least the transparent substrate coated with the stack is curved and/or tempered.

14. A glazing comprising a material according to claim 1 and one, two, or three additional substrates.

15. The glazing according to claim 14, comprising a functional coating other than the stack comprising the at least one functional metal layer, the functional coating being located:
on the transparent substrate comprising the at least one functional metal layer, on a face opposite that comprising the at least one functional metal layer, or
on a face of a substrate different from the transparent substrate comprising the at least one functional metal layer.

16. A heating or cooling device comprising a heater or cooler and an enclosure delimited by one or more walls, wherein at least one wall of the one or more walls comprises at least one glazing comprising a material according to claim 1.

17. A cooling device according to claim 16, wherein the cooling device is of a freezer and the glazing consists of the material and the stack is located on a face of the transparent substrate in contact with the enclosure.
